(19) United States
(12) Patent Application Publication
(10) Pub. No.: US 2015/0194552 A1
(43) Pub. Date: Jul. 9, 2015

(54) SOLAR CELL MODULE AND METHOD FOR MANUFACTURING THE SOLAR CELL MODULE

(71) Applicant: Panasonic Intellectual Property Mangement Co., Ltd., Osaka (JP)

(72) Inventors: Satoru Ogasahara, Aichi (JP); Wataru Shinohara, Gifu (JP)

(21) Appl. No.: 14/575,955

(22) Filed: Dec. 18, 2014

Related U.S. Application Data
(63) Continuation of application No. PCT/JP2013/001434, filed on Mar. 7, 2013.

(30) Foreign Application Priority Data
Jun. 29, 2012 (JP) 2012-147768

(51) Int. Cl. H01L 31/048; H01L 31/18; H01L 31/0224

(52) U.S. Cl. CPC H01L 31/048; H01L 31/022433; H01L 31/18

(57) ABSTRACT

A solar cell module includes a translucent member disposed at a light-receiving side, a glass plate, having a through-hole, which is provided in such a position as to face the translucent member, a photovoltaic device provided between the translucent member and the glass plate, a sealing portion that seals the through-hole, a wiring, which is connected to the photovoltaic device and which is arranged in such a manner as to extend below the sealing portion, and a conductive member arranged on top of the wiring and below the sealing portion. The sealing portion includes a glass member, joined to an inner circumferential surface of the through-hole, and a metal terminal that outputs the electric power, generated in the photovoltaic device, to the exterior. The metal terminal is joined to the glass member in a manner such that the metal terminal penetrates the glass member.

### CROSS-REFERENCE TO RELATED APPLICATIONS

This application is based upon International Application No. PCT/JP2013/001434, filed Mar. 7, 2013 and claims the benefit of priority from the prior Japanese Patent Application No. 2012-147768, filed Jun. 29, 2012, the entire contents of which are incorporated herein by reference.

### BACKGROUND OF THE INVENTION

1. Field of the Invention

The present disclosure relates to a solar cell module and a method for fabricating the solar cell modules.

2. Description of the Related Art

The so-called solar cells, or photovoltaic cells, used as photoelectric conversion devices for converting light energy into electric energy have been strenuously developed so far in many areas. A solar cell is generally a panel-shaped cell unit. Such a solar cell panel is obtained, for example, such that a transparent glass substrate, a filling adhesive, a solar battery cell, another filling adhesive and a back-side protective cover are stacked in this order and are formed integrally with each other before a peripheral end part of the integrally formed components is sealed with a sealing member. Here, in order to extract the electricity (electric power) generated by the solar battery cell, two lead wires connected to the solar battery cell pass through the back-side protective cover and are contained in a box provided outside the back-side protective cover. Accordingly, a terminal inlet, through which the two lead wires are made to pass, is provided in the back-side protective cover. Here, for the purpose of protecting it against water damage, this terminal inlet is sealed off with the filling adhesive such as silicone resin.

### SUMMARY OF THE INVENTION

However, it is difficult for the filling adhesive, such as silicone resin, used in the terminal inlet to completely prevent the water vapor from entering the panel through the terminal inlet. For this reason, there is room for further improvement in terms of sealing the terminal inlet of the solar cell module.

The present disclosure has been made in view of foregoing circumstances, and a purpose thereof is to provide a technology for improving the reliability of a solar cell module.

In order to resolve the above-described problems, a solar cell module according to one embodiment of the present disclosure includes: a translucent member disposed at a light-receiving side; a glass plate provided in such a position as to face the translucent member, the glass plate having a through-hole; a photovoltaic device provided between the translucent member and the glass plate; a sealing portion that seals the through-hole; a wiring connected to the photovoltaic device, the wiring being arranged in such a manner as to extend below the sealing portion; and a conductive member arranged on top of the wiring and below the sealing portion. The sealing portion includes: a glass member joined to an inner circumferential surface of the through-hole; and a metal terminal that outputs electric power, generated (produced) in the photovoltaic device, to an exterior, the metal terminal being joined to the glass member in a manner such that the metal terminal penetrates the glass member. The metal terminal connects to the wiring by way the conductive member.

Another embodiment of the present disclosure relates to a method for fabricating a solar module. The method includes: preparing a first module on a photovoltaic device provided on a translucent member, wherein a wiring connected to the photovoltaic device is provided in the first module; preparing a second module wherein a metal terminal, through which electric power generated (produced) in the photovoltaic device is outputted to an exterior, is fixed in a through-hole formed in a glass plate, via a glass member, in a manner such that the metal terminal penetrates the glass plate and such that the through-hole is sealed; and connecting the metal terminal to the wiring, with a conductive member placed between the metal terminal and the wiring, such that the first module and the second module face each other.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a plan view of a solar cell module, according to a first embodiment, viewed from a side of a rear surface thereof;

FIG. 2 is an enlarged view of a region A in FIG. 1;

FIG. 3 is a cross-sectional view, near a terminal box, taken along the line B-B of FIG. 1;

FIG. 4 is a front view of the interior of a terminal box shown in FIG. 1 viewed from a rear surface side thereof;

FIG. 5 is a diagram schematically showing a cross-sectional view of the photovoltaic device according to a first embodiment.

FIGS. 6A to 6C are schematic cross-sectional views to explain a method for manufacturing a photovoltaic device according to a first embodiment;

FIGS. 7A to 7E are schematic cross-sectional views to explain a method for manufacturing a photovoltaic device according to a first embodiment;

FIGS. 8A and 8B are schematic cross-sectional views to explain a method for manufacturing a photovoltaic device according to a first embodiment;

FIGS. 9A to 9C are schematic cross-sectional views to explain a method for manufacturing a solar cell module according to a first embodiment;

FIGS. 10A to 10C are schematic cross-sectional views to explain a method for manufacturing a solar cell module according to a first embodiment;

FIGS. 11A and 11B are schematic cross-sectional views to explain a method for manufacturing a solar cell module according to a first embodiment;

FIG. 12 is a plan view of a solar cell module, according to a second embodiment, viewed from a rear surface side thereof;

FIG. 13 is a cross-sectional view, near a terminal box, taken along the line C-C of FIG. 12;

FIG. 14 is a front view of the interior of a terminal box shown in FIG. 12 viewed from a rear surface side thereof;

FIG. 15 is a diagram showing a modification of the melt-bonding of a translucent member and a back-side glass plate;

FIG. 16 is a diagram showing another modification of the melt-bonding of a translucent member and a back-side glass plate; and

FIG. 17 is a graph showing a change in a maximum output point in a high-temperature and high-humidity testing.

### DETAILED DESCRIPTION OF THE INVENTION

To promote wide use of solar cells, it is necessary to reduce the power generation cost. In order to achieve this, it is effective to make the life of a photovoltaic device longer. One of factors in hindering the prolonged life thereof is the infiltration of moisture or water content into the panels of a solar cell module. At the same time, as discussed earlier, for the purpose of preventing the water content from entering the panels thereof, the peripheral end part thereof is sealed with the sealing member, and the terminal inlet is sealed with a resin material having a low moisture vapor transmission rate.

However, pinholes are likely to occur in the resin material and it is difficult for the moisture vapor transmission rate to become completely zero in terms of the material used. For this reason, there is room for further improvement in terms of the moisture-proof property even though the waterproof property has already been taken into account about the sealing member made of the resin material. Through their diligent investigations in view of the foregoing circumstances, the inventors of the present disclosure had come to arrive at technical ideas underlying the present disclosure where the reliability of the solar cell module can be improved.

A solar cell module according to one embodiment in embodiments described hereinafter includes: a translucent member disposed at a light-receiving side; a back-side glass plate provided in such a position as to face the translucent member, the back-side glass plate having a through-hole; a photovoltaic device provided between the translucent member and the back-side glass plate; a sealing portion that seals the through-hole; a wiring connected to the photovoltaic device, the wiring being arranged in such a manner as to extend below the sealing portion; and a conductive member arranged on top of the wiring and below the sealing portion. The sealing portion includes: a glass member joined to an inner circumferential surface of the through-hole; and a metal terminal that outputs electric power, generated in the photovoltaic device, to an exterior, the metal terminal being joined to the glass member in a manner such that the metal terminal penetrates the glass member. The metal terminal connects to the wiring by way the conductive member.

By employing this embodiment, the through-hole in which the metal terminal, which outputs the electric power (electricity) generated by the photovoltaic device to the exterior, is provided, is sealed with the glass member. Thus, the filtration of water vapor (moisture) into the solar cell module can be further reduced. As a result, the degradation of the photovoltaic device and the wirings due to the water vapor is suppressed over a long period of time and therefore the reliability of the solar cell module can be improved.

The conductive member may be a conductive film. Thereby, the metal terminal and the wiring can connect to each other while the thickness of the solar cell module is suppressed.

The conductive film may have an adhesion layer and metallic particles dispersed in the adhesion layer. Thereby, the connection reliability of the metal terminal and the wiring is improved, and the thermal stress can be mitigated.

The photovoltaic device may be arranged such that, as the through-hole is viewed from top, a part of the photovoltaic device overlaps with the conductive member. Thus, even though the conductive member and the photovoltaic device are located closer to each other, the metal terminal and the wiring can be connected to each other by the conductive member.

The glass member may be a low-melting-point glass whose glass transition temperature thereof is 600° C. or below. Thereby, the glass member and the back-side glass plate can be jointed to each other without a thermal treatment at a high temperature.

The back-side glass plate may be formed such that a periphery of the back-side glass plate is melt-bonded to the translucent member. This suppresses the water vapor from entering the solar cell module through a gap, between the back-side glass plate and the translucent member, on a periphery of the solar cell module. Hence, the reliability of the solar cell module can be further improved.

Another embodiment in the embodiments relates to a method for fabricating a solar cell module. This method includes: a process for preparing a first module on a photovoltaic device provided on a translucent member, wherein a wiring connected to the photovoltaic device is provided in the first module; a process for preparing a second module wherein a metal terminal, through which electric power generated in the photovoltaic device is outputted to an exterior, is fixed in a through-hole formed in a back-side glass plate, via a glass member, in a manner such that the metal terminal penetrates the back-side glass plate and such that the through-hole is sealed; and a process for connecting the metal terminal the with a conductive member placed between the metal terminal and the wiring, such that the first module and the second module face each other.

arranging the first module and the second module.

By employing this embodiment, in a state where the through-hole is being sealed with the glass member, the back-side glass plate and the translucent member face each other. And the metal terminal and the wiring are connected to each other via the conductive member with. Thus, in particular, the filtration of water vapor (moisture) into the solar cell module through the through-hole can be further reduced.

In the above-described method for fabricating the solar cell module, a conductive film, having an adhesion layer and metallic particles dispersed in the adhesion layer, may be used as the conductive member, and the process for connecting the metal terminal to the wiring may be performed such that heating is carried out at a temperature at which at least the conductive film is softened. Thereby, the connection reliability of the metal terminal and the wiring is improved, and the thermal stress can be mitigated.

Hereinbelow, the preferred embodiments will be described with reference to the accompanying drawings. Note that in all of the Figures the identical reference numerals are given to the identical components and the description thereof is omitted as appropriate,

The scale reduction and the form of each layer and each component shown in each of the following Figures are conveniently set for the ease of explanation and should not be construed in a limited extent unless otherwise explicitly specified.

### First Embodiment

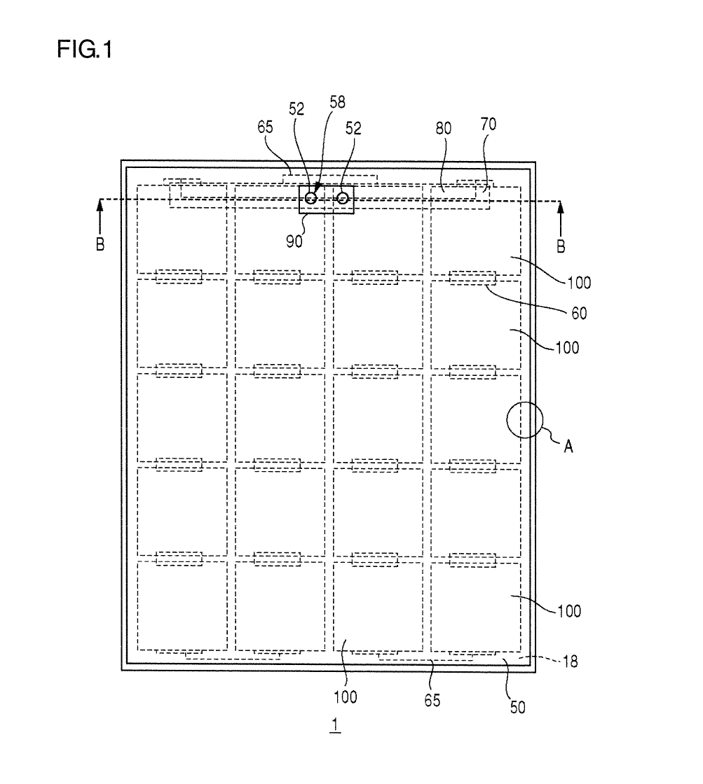

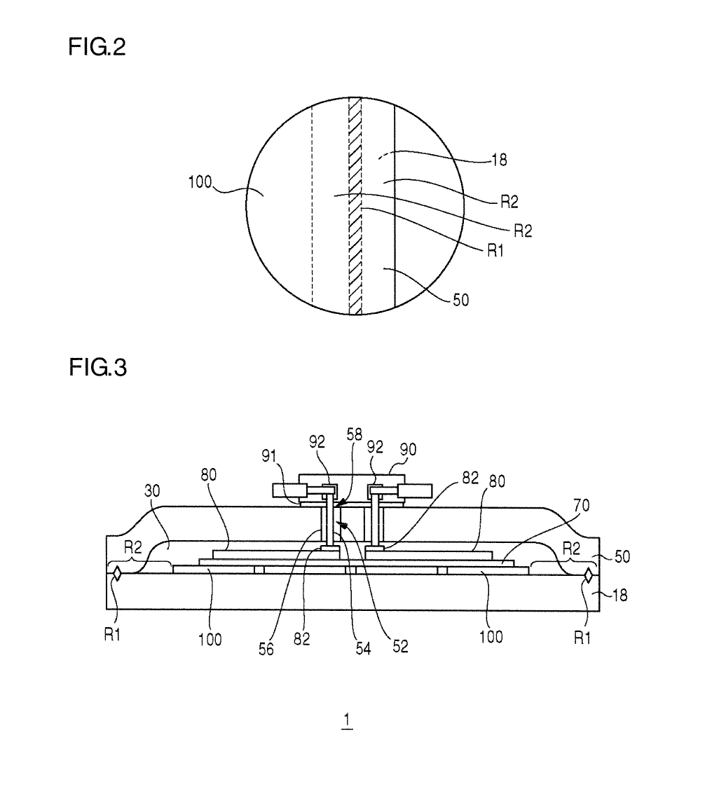

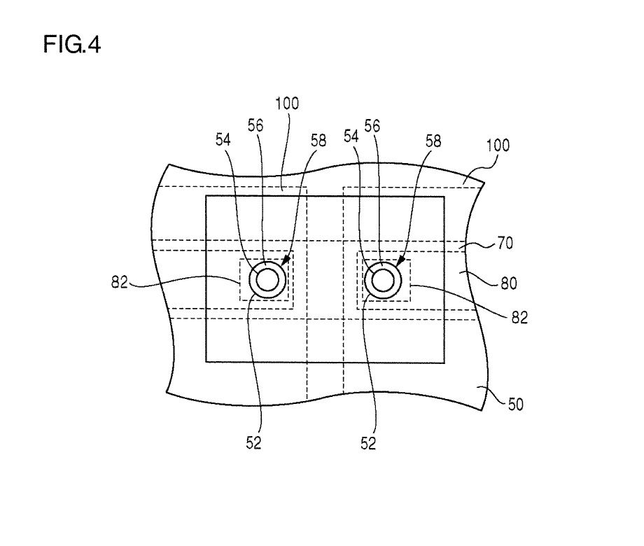

FIG. 1 is a plan view of a solar cell module 1, according to a first embodiment, viewed from a rear surface side thereof. FIG. 2 is an enlarged view of a region A in FIG. 1. FIG. 3 is a cross-sectional view, near a terminal box 90, taken along the line B-B of FIG. 1. FIG. 4 is a front view of the interior of the terminal box 90 shown in FIG. 1 viewed from a side of the rear surface thereof.

The solar cell module 1 includes a translucent member 18, which is disposed on a light-receiving surface side, a back-side glass plate 50, which is so provided as to face the translucent member 18, and a photovoltaic device 100 provided between the translucent member 18 and the back-side glass plate 50.

For example, a glass plate, which is a square of 1 m by 1 m and whose sheet thickness is 4 mm, is used for the translucent member 18. However, a material used for the translucent member 18 should not be considered as limiting. For example, a resin board or the like may be used instead as long as it can transmit the light having a wavelength band used for the power generation at the photovoltaic device 100, can mechanically support the photovoltaic device 100, and can protect the photovoltaic device 100 against an outside environment. The incident light to the solar cell module 1 basically enters thereto from a translucent member 18 side. The glass plate may be thinner if a predetermined strength required for the solar cell module as a whole is met, and a glass plate, whose sheet thickness is 3.2 mm, for instance, may be used.

The back-side glass plate 50 is so provided as to cover the photovoltaic device 100 formed on top of the translucent member 18. The back-side glass plate 50 is, example, approximately equal in size to that of the translucent member 18. For example, a glass plate whose sheet thickness is 3.2 mm is used as the back-side glass plate 50. However, such examples are non-limiting.

The translucent member 18 and the back-side glass plate 50 are fusion-joined (melt-bonded) to each other in a joining region R1 of their outer peripheral edge regions. The joining region R1 is provided in a peripheral region R2 of the translucent member 18 where no photovoltaic device 100 is provided. In order to melt-bond the translucent member 18 and the back-side glass plate 50, a peripheral part of at least one of the translucent member 18 and the back-side glass plate 50 is preferably or suitably bent or warped as shown in FIG. 3.

As a filler 30, such a resin material as listed below is preferably placed between the back-side glass plate 50 and the photovoltaic device 100. That is, the resin material preferably used as the filler 30 may include ethylene-vinyl acetate (hereinafter referred to as EVA), polyvinyl butyral (hereinafter referred to as PVB), and various types of olefin-based resins. The glass plate and the components including the photovoltaic device are firmly attached to each other by the filler 30 and therefore the overall strength of the solar cell module 1 is enhanced. In order to enhance the reflectivity of light on the back-side, a reflective layer may be provided between the filler 30 and the back-side glass plate 50, and the filler itself may be formed as a colored resin. For example, a filler mixed with titanium oxide particles may be used; the reflection effect of the filler mixed therewith is further enhanced and thereby the conversion efficiency of the solar cell module 1 is improved.

The photovoltaic device 100 is a back-side bonding type (back-contact type) photovoltaic device where no electrodes is provided on the light-receiving surface side but the electrodes are provided on the back-side only.

With reference to FIG. 5, a description is now given of principal components of the photovoltaic device 100. FIG. 5 is a diagram schematically showing a cross-sectional view of the photovoltaic device 100 according to a first embodiment.

A base layer 14 of the photovoltaic device 100, which functions as a power generation layer thereof, is a crystalline semiconductor layer. In the present embodiment, it is assumed that the base layer 14 is an n-type crystalline silicon layer doped with an n-type dopant. The doping concentration of the base layer 14 is about 10¹⁶/cm³, for instance. The film thickness of the base layer 14 is preferably such that the base layer 14 can sufficiently produce carriers, and the film thickness thereof is in a range between 1 μm and 100 μm (both inclusive), for instance. Assume herein that a “crystalline” substance includes not only a single crystal but also a polycrystal where a multiplicity of crystal grains are gathered.

A passivation layer 16 is provided between the translucent member 18 and the base layer 14. The passivation layer 16 plays a role of, for instance, terminating the dangling bonds in the surface of Si contained in the base layer 14, and suppresses the recombination of carries on the surface of the base layer 14. Provision of the passivation layer 16 can suppress the loss caused by the recombination of carriers on the surface of the base layer 14 at the light-receiving surface side of the photovoltaic device 100. The passivation layer 16 is formed such that, for example, a silicon nitride (SiN) layer is included in the passivation layer 16, and the passivation layer 16 is more preferably of a stacked structure such that a silicon oxide (SiOₓ) layer and a silicon nitride layer are stacked together. For example, a SiOₓ layer and a SiN layer may be stacked in sequence wherein the film thickness of the SiOₓ layer and the thickness of the SiN are 30 nm and 40 nm, respectively.

The passivation layer 16 and the translucent member 18 are structured such that the passivation layer 16 and the translucent member 18 are directly joined to each other without adhesive applied therebetween. A method for directly joining or bonding the translucent member 18 and the passivation layer 16 includes an anodic bonding and a normal temperature welding, for instance. In the anodic bonding, the translucent member 18 and the passivation layer 16 are joined together by applying a voltage therebetween. In the normal temperature welding, the surface of the translucent member 18 and the surface of the passivation layer 16, which have been reformed by ion beams in high vacuum, are joined together. Instead of directly joining the translucent member 18 and the passivation layer 16, the translucent member 18 and the passivation layer 16 may be bonded together with adhesive that transmits the light having a wavelength band used for the power generation at the photovoltaic device 100. The adhesive as used herein may be EVA, PVB, silicone, or various types of olefin-based resins, for instance.

A first conductive-type layer 12 is a crystalline semiconductor layer. In the present embodiment, it is assumed that the first conductive-type layer 12 is an n-type crystalline silicon layer doped with an n-type dopant. The first conductive-type layer is a layer bonded to a metallic layer, and the doping concentration of the first conductive-type layer is higher than that of the base layer 14. The doping concentration of the first conductive-type layer is preferably about 10¹⁹/cm³. The film thickness of the first conductive-type layer 12 is preferably as small as possible within a range where the contact resistance with a metal is sufficiently low, and the thickness thereof is preferably in a range between 0.1 μm to 2 μm (both inclusive), for instance.

The base layer 14 and the first conductive-type layer 12 form a first conductive-type contact region C1 where a homo-junction occurs among the crystalline substances thereof. For example, the first conductive-type contact region C1 is formed in a comb shape and includes fingers and bus bars within a surface of the photovoltaic device 100. The area of the first conductive-type contact region C1 indicates an area of the homo-junction with the first conductive-type layer 12 in a main surface of the base layer 14.

An insulating layer 20 is used to electrically insulate between the first conductive-type layer 12, an i-type layer 22 and a second conductive-type layer 24 discussed later. The insulating layer 20 is also used as a mask when the first conductive-type layer 12 is etched. The insulating layer 20 is constructed of a material with insulation properties and may be silicon nitride (SiN), for instance. The film thickness of the insulating layer 20 may be about 100 nm, for instance.

The i-type layer 22 and the second conductive-type layer 24 are each formed as an amorphous-based semiconductor layer. An “amorphous-based” substance includes an amorphous phase or a microcrystalline layer where fine crystal grains are precipitated in the amorphous phase. In the present embodiment, the i-type layer 22 and the second conductive-type layer 24 are each formed of amorphous silicon containing hydrogen. The i-type layer 22 is practically an intrinsic amorphous silicon layer. The second conductive-type layer 24 is an amorphous silicon layer doped with a p-type dopant. The doping concentration of the second conductive-type layer 24 is higher than that of the i-type layer 22.

For example, the i-type layer 22 is intentionally not doped, and the doping concentration of the second conductive-type layer 24 may be about 10¹⁸/cm³, for instance. The film thickness of the i-type layer 22 is made smaller to suppress the absorption of light as much as possible, whereas the i-type layer 22 is made thick to the degree that the surface of the base layer 14 can be sufficiently passivated. More specifically, the thickness thereof is may be in a range between 1 nm and 50 nm (both inclusive) and is 10 nm, for instance. Also, the film thickness of the second conductive-type layer 24 is made smaller to suppress the absorption of light as much as possible, whereas the second conductive-type layer 24 is made thick to the degree that the open voltage of the photovoltaic device 100 is sufficiently high. For example, the thickness thereof may be in a range between 1 nm and 50 nm (both inclusive) and is 10 nm, for instance.

A transparent electrode layer 26 may preferably be made of at least one of transparent conductive oxides (TCO) or made of a combination of two or more of transparent conductive oxides (TCO) in which tin oxide (SnO₂), zinc oxide (ZnO), indium tin oxide (ITO), or the like is doped with tin (Sn), antimony (Sb), fluorine (F), aluminum (Al) or the like. It is advantageous in that, among them, zinc oxide (ZnO) in particular is high in translucency, low in resistivity, and so forth. The film thickness of the transparent electrode layer 26 is preferably in a range between 10 nm and 500 nm (both inclusive) and is 100 nm, for instance.

The base layer 14, the i-type layer 22 and the second conductive-type layer 24 form a second conductive-type contact region C2 where crystals and non-crystals are hetero-junctioned. For example, the second conductive-type contact region C2 includes fingers and bus bars within the surface of the photovoltaic device 100, and is formed in a comb shape combined with the first conductive-type contact region C1. The area of the second conductive-type contact region C2 indicates an area of the hetero-junction with the i-type layer and the second conductive-type layer in the main surface of the base layer 14. A pattern is preferably formed such that the area of the first conductive-type contact region C1 is smaller than that of the second conductive-type contact region C2.

Metallic layers 28 are layers that form the electrodes provided on a back side of the photovoltaic device 100. A metallic layer 28 is constituted by a conductive material such as a metal and is a material containing copper (Cu) or aluminum (Al), for instance. The metallic layers 28 include a first electrode 28n, which is connected to the first conductive-type layer 12, and a second electrode 28p, which is connected to the second conductive-type layer 24. The metallic layers 28 may further contain an electrolytic plating layer such as copper (Cu) or tin (Sn). However, this should not be considered as limiting and, for example, the metallic layers 28 may be formed of other metals, such as gold (Au) and silver (Ag), other conductive materials, or a combination thereof.

As illustrated in FIG. 1, the solar cell module 1 has a plurality of photovoltaic devices 100. The plurality of photovoltaic devices 100 are disposed in a matrix on the translucent member 18. The plurality of photovoltaic devices 100 are connected in series with each other by way of current-collecting wirings (first current-collecting wirings 60 and 65) that interconnect the first electrode 28n of one photovoltaic device 100 with the second electrode 28p of another photovoltaic device 100 adjacent thereto. In the solar cell module 1 shown in FIG. 1, twenty photovoltaic devices 100 are connected in series with one another. Depending on the application of the solar cell module 1, the photovoltaic devices 100 may possibly be connected in parallel with each other or may be of a combined configuration such that some of them are connected in series and the remaining of them are connected in parallel.

Second current-collecting wirings 80 for extracting the electricity (electric power), generated by the photovoltaic devices 100, to the terminal box are connected to the both ends of the photovoltaic devices 100 connected in series with each other, respectively.

The material used for the first current-collecting wirings 60 and 65 and the second current-collecting wiring 80 is normally Cu but other metals, such as Al, which have low resistivity may be used instead. Where the current-collecting wirings are made of Cu, those plated with Sn or the like are preferable or suitable. A material used for the connection between the first current-collecting wirings 60 and 65 and the first electrode 28n and the second electrode 28p may be a metallic material, such as solder and pasty Ag or Cu, or a conductive film. The conductive film as used herein may be a film using a conductive resin, a resin film with metallic particles mixed therein and so forth, for instance.

Where the photovoltaic device 100 is to be made thinner, it is preferable that a conductive film capable of suppressing the thermal stress damage to the photovoltaic device 100 is used to connect the photovoltaic devices 100 using the first electrode 28n (or the second electrode 28p) and the first current-collecting wirings 60 and 65.

As illustrated in FIG. 1, FIG. 3 and FIG. 4, the second current-collecting wirings 80 are disposed on the photovoltaic device 100 with an insulating coating material 70 placed between the second current-collecting wirings 80 and the photovoltaic device 100.

The insulating coating material 70 and the second current-collecting wirings 80 are extended, over a back-side electrode (the metallic layer 28) of the photovoltaic device 100, up to a position where the insulating coating material 70 and the second current-collecting wirings 80 overlap with through-holes 52 formed on the back-side glass plate 50. The insulating coating material 70 as used herein may preferably be polyester (PE), polyethylene terephthalate (PET), polyethylene naphthalate (PEN), polyimide, polyvinyl fluoride or the like, for instance. Also, it is preferable to use one, to which a seal-like adhesive is applied on the rear face, as the insulating coating material 70.

As shown in FIG. 4, a current extraction member of the solar cell module 1 is provided in the surface of the back-side glass plate 50, and includes a metal terminal 54 that functions as an electrically-conducting path through which the electric power generated in the photovoltaic device 100 is outputted to the exterior. In the back-side glass plate 50, two through-holes 52, each of whose diameter is 6 mm, are formed in predetermined positions (on a top end side in FIG. 1) and are located above photovoltaic devices 100.

The through-hole 52 is sealed by a sealing member 58. The sealing member 58 has a low-melting-point glass 56, which is used as a glass member joined to an inner circumferential surface of the through-hole 52, and a metal terminal 54, which is joined to the back-side glass plate 50 in such a manner as to penetrate the low-melting-point glass 56. In other words, the metal terminal 54 is placed in the through-hole 52 such that the through-hole 52 runs through the metal terminal 54. Also, the metal terminal 54 is melt-bonded to the back-side glass plate 50, in the inner circumferential surface of the through-hole 52, via the low-melting-point glass 56 (i.e., with the low-melting-point glass 56 placed between the metal terminal 54 and the back-side glass plate 50). For the low-melting-point glass 56, the glass transition temperature thereof is preferably 600° C. or below, more preferably 400° C. or below, or most preferably 300° C. or below. Preferable in particular is a temperature at which the glass is softened by a lamination process discussed later. This allows the low-melting-point glass 56 and the back-side glass plate 50 to be joined to each other without a thermal treatment at a high temperature.

The low-melting-point glass 56 as used herein may be P₂O₅—CuO—ZnO-based low-melting-point glass, P₂O₅—SnO-based low-melting-point glass, B₂O₃—ZnO—Bi₂O₃—Al₂O₃-based low-melting-point glass or the like, for instance. The metal terminal 54 may be an alloy of iron and nickel with a ratio of iron to nickel being 50:50, for instance. Such an alloy as the aforementioned has a linear expansion coefficient that is relatively close to that of the low-melting-point glass, so that the occurrence of cracks or the like otherwise caused by a thermal expansion of the low-melting-point glass can be suppressed.

As illustrated in FIG. 1 and FIG. 4, the second current-collecting wiring 80 is arranged such that the second current-collecting wiring 80 is connected to the photovoltaic device 100 and extend below the sealing member 58. A conductive film 82, which serving as a conductive member, is arranged on top of the second current-collecting wiring 80 and is also arranged below the sealing member 58. The conductive film 82 is arranged on top of the second current-collecting wiring 80 and is placed underneath the metal terminal 54, which is placed in the through-hole 52 (see FIG. 3 and FIG. 4). A top face of the conductive film 82 is in contact with a lower end of the metal terminal 54, whereas a bottom face thereof is in contact with a top face of the second current-collecting wiring 80. Thus, the conductive film 82 electrically conducts between the metal terminal 54 and the second current-collecting wiring 80. In other words, the second current-collecting wiring 80 and the metal terminal 54 electrically conduct with each other via the conductive film 82 placed therebetween.

The metal terminal 54 is connected to a connection metal terminal 92 inside the terminal box 90 by using a solder or a metallic clip-like attachment. The terminal box 90 is bonded to the back-side glass plate 50 by a silicone-based or acrylic-based adhesive 91.

In the solar cell module 1 according to the present embodiment, the through-hole 52, in which the metal terminal 54 is provided, is sealed with the low-melting-point glass 56, which is a glass member. Here, the electric power generated by the photovoltaic device 100 is outputted to the exterior through the metal terminal 54. This structure where the through-hole 52 is sealed therewith can further reduce the infiltration of water vapor (moisture) into the solar cell module 1. As a result, the degradation of the photovoltaic device 100 and the wirings (the first current-collecting wirings 60 and 65 and the second current-collecting wiring 80) due to the water vapor is suppressed over a long period of time and therefore the reliability of the solar cell module 1 can be improved.

Also, the conductive member is constructed of the conductive film 82. This allows the metal terminal 54 to be connected with the second current-collecting wiring 80 while the thickness of the solar cell module 1 is suppressed.

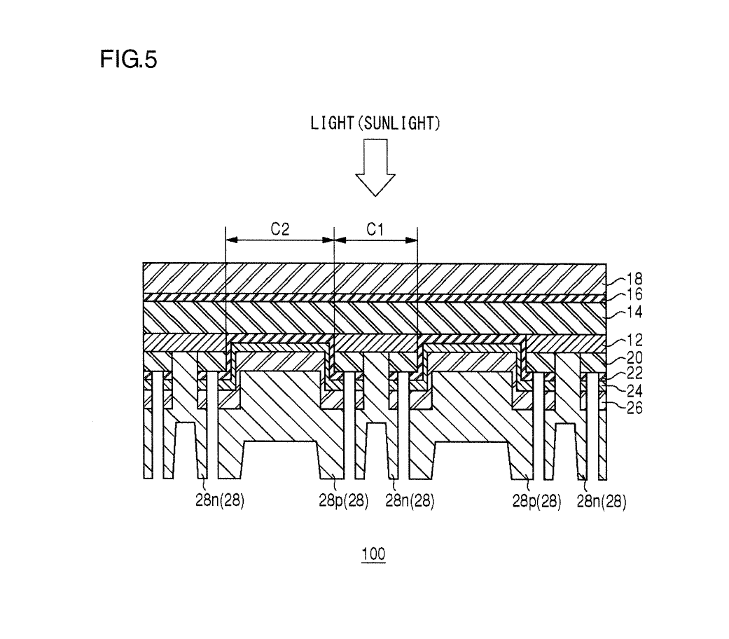

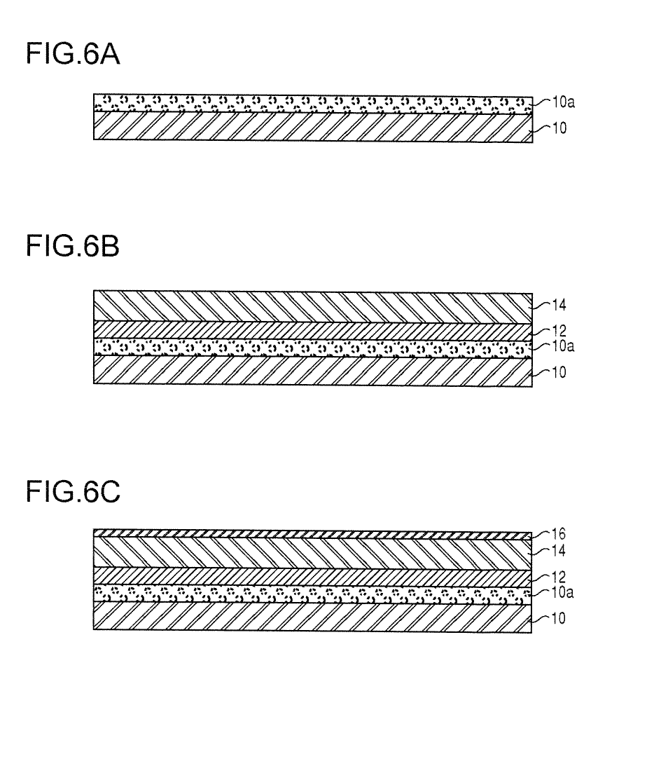

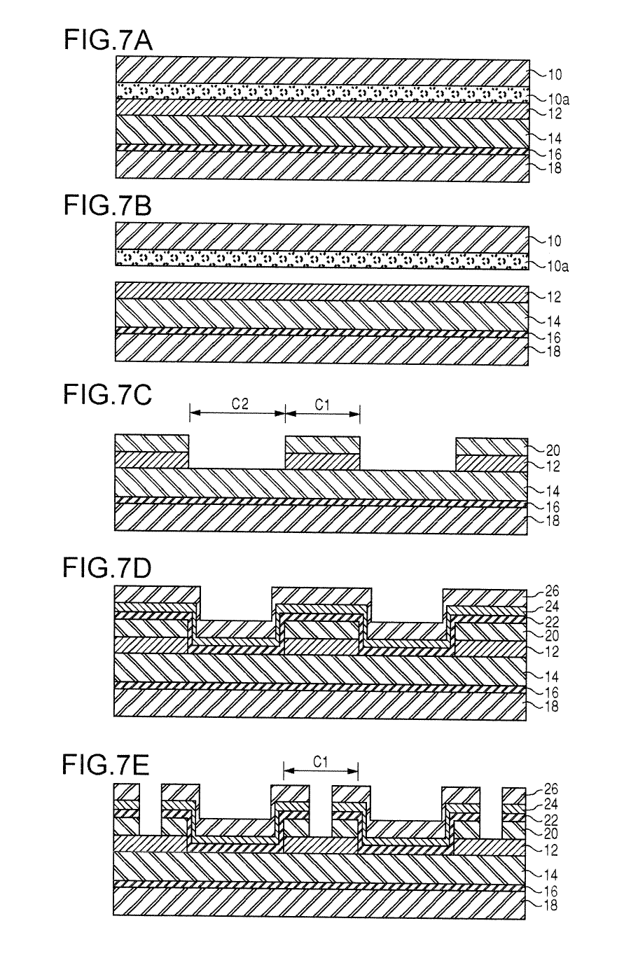

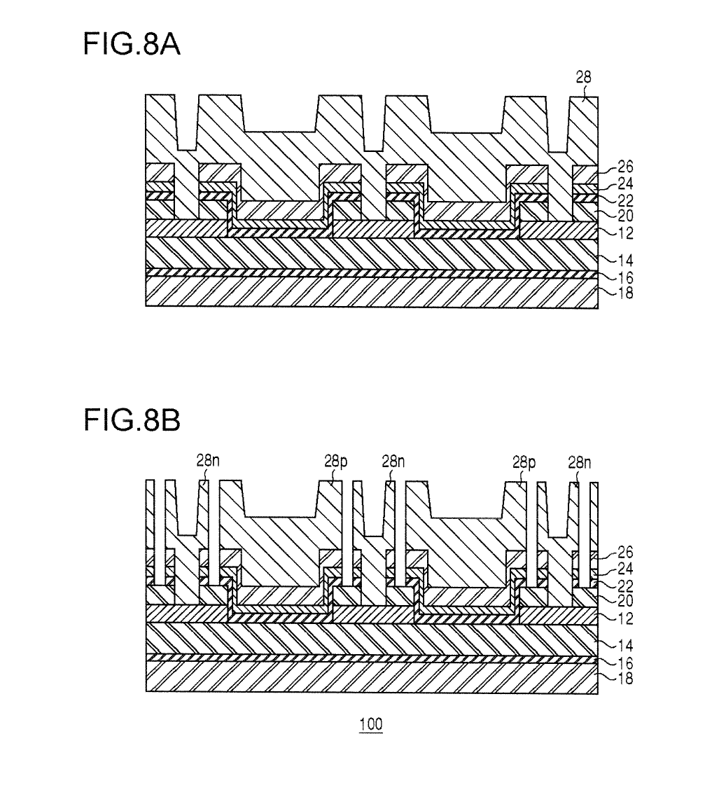

A description is now given of a method for manufacturing a solar cell module 1 according to the first embodiment. FIGS. 6A to 6C are schematic cross-sectional views to explain a method for manufacturing a photovoltaic device 100 according to the first embodiment. FIGS. 7A to 7E are schematic cross-sectional views to explain a method for manufacturing the photovoltaic device 100 according to the first embodiment FIGS. 8A and 8B are schematic cross-sectional views to explain a method for manufacturing the photovoltaic device 100 according to the first embodiment. For clarification of explanation, the positions of components shown in FIGS. 6A to 6C are tuned upside down in FIGS. 7A to 7E and FIGS. 8A and 8B. In FIGS. 6A to 8B, a description is given by directing attention to a single photovoltaic device. However, as will be described later, a plurality of photovoltaic devices are simultaneously formed on a translucent member when a solar cell module is to be fabricated.

The base layer 14 used in the photovoltaic device 100 is formed of a crystalline semiconductor material. For example, the base layer 14 is a semiconductor substrate made of silicon, polycrystalline silicon, gallium arsenide (GaAs), indium phosphide (InP) or the like.

In the present embodiment, an example is shown where a single-crystal silicon substrate is used as the base layer 14. Thus, it is assumed herein that the first conductive-type layer 12, the base layer 14, the i-type layer 22 and the second conductive-type layer 24 described later are silicon layers as well. A substrate 10 used for the base layer 14 may be formed of a material other than silicon and each of other layers may also be formed of a material other than silicon.

A porous layer 10a is formed on one main surface of the substrate 10 (FIG. 6A). The porous layer 10a can be formed by anodic oxidation, for instance. An electrolyte used in the anodic oxidation may be a mixed liquid of hydrofluoric acid and ethanol or a mixed liquid of hydrofluoric acid and hydrogen peroxide water. The current density in the anodic oxidation may be in a range between 5 mA/cm² and 600 mA/cm² (both inclusive) and is about 10 mA/cm², for instance.

The thickness of the porous layer 10a is preferably in a range between 0.01 μm and 30 μm (both inclusive) and is about 10 μm, for instance. The pore diameter of the porous layer 10a is preferably in a range between 0.002 μm and 5 μm (both inclusive) and is about 0.01 μm, for instance. The porosity ratio of the porous layer 10a is preferably in a range between 10% and 70% (both inclusive) and is about 20%, for instance.

The first conductive-type layer 12 and the base layer 14 are formed on the porous layer 10a of the substrate 10 (FIG. 6B). The first conductive-type layer 12 and the base layer 14 are formed using a chemical vapor deposition (CVD method). The first conductive-type layer 12 and the base layer 14 are formed by epitaxial growth where the porous layer 10a is used as a seed layer, thereby forming a homo-junction region where crystalline semiconductor layers are bonded to each other. For example, the substrate 10 is heated to a temperature of 950° C. and dichlorosilane (SiH₂Cl₂) diluted with hydrogen (H₂) is supplied as a material gas, thereby forming the first conductive-type layer 12 and the base layer 14. The flow rate of hydrogen (H₂) and dichlorosilane (SiH₂Cl₂) are set to 0.5 (l/min) and 180 (l/min), respectively. Also, when needed, phosphine (PH₃) is added as a doping gas.

The passivation layer 16 is formed on top of the base layer 14 (FIG. 6C). If the passivation layer 16 is formed of silicon nitride (SiN), the passivation layer 16 can be formed using a plasma-enhanced chemical vapor deposition (PECVD method). In this PECVD method, a material gas, in which oxygen (O₂) and/or nitrogen (N₂) are mixed with silane (SiH₄), is turned into plasma and supplied so as to form the passivation layer 16.

A plurality of substrates 10, in which those layers up to the passivation layers 16 have been formed, are prepared and then the passivation layer 16 of each substrate 10 is directly bonded to the translucent members 18 formed of a glass plate (FIG. 7A). Though, not particularly depicted in FIG. 7A, the plurality of passivation layers 16 (the plurality of substrates 10 in which those layers up to the passivation layers 16 have been formed) are being directly bonded to the translucent members 18, in this fabrication process.

A method for directly bonding the translucent member 18 and the passivation layer 16 includes the anodic bonding and the normal temperature welding, for instance. In the anodic bonding, the translucent member 18 and the passivation layer 16 are joined together by applying a voltage therebetween. In the normal temperature welding, the surface of the translucent member 18 and the surface of the passivation layer 16, which have been reformed by ion beams in high vacuum, are joined together.

Where the anodic bonding is used, the translucent member 18 and the passivation layer 16 can be joined together by applying a voltage of several hundreds of volts or more therebetween at a temperature of 200 to 400° C., for instance. The translucent member 18 as used here is preferably a glass, which contains an alkaline component and whose linear expansion coefficient is close to that of the substrate to be bonded thereto. For example, borosilicate glass is suitable if a Si substrate is used.

Where the normal temperature welding is used, molecules bonded with atoms of the outermost Si on the side of laminating surfaces of the translucent member 18 (e.g., glass) and the passivation layer 16 (e.g., SiN) are removed by using Ar ion beam in a high vacuum of 10⁻⁶ Pa or below. In other words, the translucent member 18 and the passivation layer 16 can be bonded in a short time, when they are joined together while their bonding hands (dangling bonds) are located at the outermost surface thereof. When the normal temperature welding is used, the bonding is possible even though no alkaline components is contained in the translucent member 18. Thus, alkali-free glass can be used in the normal temperature welding.

The translucent member 18 may be bonded to the passivation layer 16 by using adhesive or the like. The adhesive is preferably made of a material that transmits the light having a wavelength band used for the power generation at the photovoltaic device 100. The adhesive as used herein may be EVA, PVB, silicone, or various types of olefin-based resins, for instance.

Then, the substrate 10 is separated using the porous layer 10a (FIG. 7B). The substrate 10 can be separated by using a mechanical treatment. For example, the substrate 10 and the translucent member 18 are adsorbed by vacuum chucks and then both of them are pulled in such a manner as to separated off from each other, thereby separating the substrate 10 from a porous layer 10a portion. Also, the substrate 10 can be separated from the porous layer 10a portion by spraying a water jet on the porous layer 10a from a side surface of the substrate 10. If part of the porous layer 10a stays on a first conductive-type layer 12 side, the part thereof staying thereon may be removed by etching, for example, in which used is fluonitric acid where hydrofluoric acid (HF) and nitric acid (HNO₃) are mixed together.

After separated from the substrate 10, the insulating layer 20 is formed on top of the first conductive-type layer 12 and, at the same time, the first conductive-type layer 12 is patterned (FIG. 7C). The insulating layer 20 can be formed using the plasma-enhanced chemical vapor deposition (PECVD method) where a material gas, in which nitrogen (N₂) is mixed with silane (SiH₄), is turned into plasma and supplied.

The patterning can be carried out using etching paste. Etching past containing phosphoric acid is applied to an intended pattern by using a screen printing method or the like and thereby the first conductive-type layer 12 together with the insulating layer 20 are partially removed. Also, in order to achieve an intended pattern, the insulating layer 20 may be partially removed by dry etching, and the first conductive-type layer 12 may be partially removed by using the insulating layer 20 as a mask, by the dry etching or wet etching. Reactive ion etching (RIE) where carbon tetrafluoride (CF₄) is used may be employed in the dry etching of the insulating layer 20. Reactive ion etching (RIE) where sulfur hexafluoride (SF₆) is used may be employed in the dry etching of the first conductive-type layer 12. An etchant containing hydrofluoric acid may be used in the wet etching of the first conductive-type layer 12.

The insulating layer 20 and the first conductive-type layer 12 are preferably patterned such that the electric power can be collected as uniformly as possible from the back side of the photovoltaic device 100. For example, the pattern is preferably formed in a comb shape and includes fingers and bus bars used in general. The pattern is preferably formed such that the first conductive-type contact region C1 is smaller than the second conductive-type contact region C2.

The i-type layer 22, the second conductive-type layer 24 and the transparent electrode layer 26 are formed on the partially exposed base layer 14 and the insulating layer 20 (FIG. 7D). The i-type layer 22 and the second conductive-type layer 24 can be formed by a PECVD method where a silicon-containing gas, such as silane (SiH₄), is used. A high-frequency power is supplied to a high-frequency electrodes from a high-frequency power source while the silicon-containing gas, such as silane (SiH₄), is supplied. As a result, plasma in the material gas is generated and a raw material is supplied on the base layer 14 and the insulating layer 20 from the plasma so as to form a silicon thin film. A dopant-containing gas such as diborane (B₂H₆) is mixed with the material gas as necessary. The transparent electrode layer 26 can be formed by sputtering or a like method.

Then, the i-type layer 22, the second conductive-type layer 24 and the transparent electrode layer 26, which are formed in the entire surface, and the insulating layer 20 are patterned (FIG. 7E). The patterning can be carried out using etching paste. Etching past containing phosphoric acid is applied to an intended pattern by the screen printing method or the like and thereby the i-type layer 22, the second conductive-type layer 24, the transparent electrode layer 26 and the insulating layer 20 are partially removed.

In this case, the patterning is carried out such that regions excluding those with which the i-type layer 22 is directly in contact with the base layer 14 are removed. In other words, partially removed are the i-type layer 22, the second conductive-type layer 24, the transparent electrode layer 26 and the insulating layer 20 disposed on the first conductive-type contact region C1 including the residuals of the insulating layer 20 and the first conductive-type layer 12. The pattern is set such that the electric power can be collected as uniformly as possible from the back side of the photovoltaic device 100. For example, the pattern is preferably a comb-shape pattern combined alternately with a comb-shape pattern of the first conductive-type layer 12.

The metallic layer 28 is formed on a patterned surface (FIG. 8A). The metallic layer 28 can be formed by the sputtering, the plasma-enhanced chemical vapor deposition (PECVD method) or a like method.

The i-type layer 22, the second conductive-type layer 24, the transparent electrode layer 26 and the metallic layer 28 are partially removed (FIG. 8B). As a result, the metallic layer 28 is so divided that there are formed the first electrodes 28n, which are connected to the first conductive-type layer 12, and the second electrodes 28p, which are connected to the transparent electrode layer 26.

The i-type layer 22, the second conductive-type layer 24, the transparent electrode layer 26 and the metallic layer 28 can be partially removed by laser etching. Also, a resist may be applied by the screen printing method so as to form a patterned mask and then the i-type layer 22, the second conductive-type layer 24, the transparent electrode layer 26 and the metallic layer 28 may be separately etched using the thus formed mask. If the metallic layer 28 is copper (Cu), ferric chloride may be used as an etchant; if the metallic layer 28 is aluminum (Al), phosphoric acid may be used as the etchant. An etchant containing hydrochloric acid (HCl) may be used in the etching of the transparent electrode layer 26. An etchant containing hydrofluoric acid (HF) may be used in the etching of the i-type layer 22 and the second conductive-type layer 24.

In this process, the i-type layer 22, the second conductive-type layer 24, the transparent electrode layer 26 and the metallic layer 28 are partially removed so that the first electrode 28n, which is connected to the first conductive-type layer 12, and the second electrode 28p, which is connected to the second conductive-type layer 24, can be electrically separated from each other. In the present embodiment, removed are partial regions of the i-type layer 22, the second conductive-type layer 24, the transparent electrode layer 26 and the metallic layer 28 stacked on a region of the insulating layer 20 left on the first conductive-type layer 12.

A metallic layer may further be laminated on the first electrodes 28n and the second electrodes 28p by electrolytic plating or the like. For example, the metallic layer is further formed with the electrolytic plating of copper (Cu) or tin (Sn) thereon. The electrolytic plating is employed while an electric potential is applied to the first electrodes 28n and the second electrodes 28p. Thus, the metallic layer is laminated only on a region where the first electrodes 28n and the second electrodes 28p remain unremoved.

In the photovoltaic device 100 formed as above, the translucent member 18 constitutes the light-receiving side surface thereof, and both the first electrode 28n and the second electrode 28p are provided on the back side. This achieves the photovoltaic device 100 of the back-side bonding type.

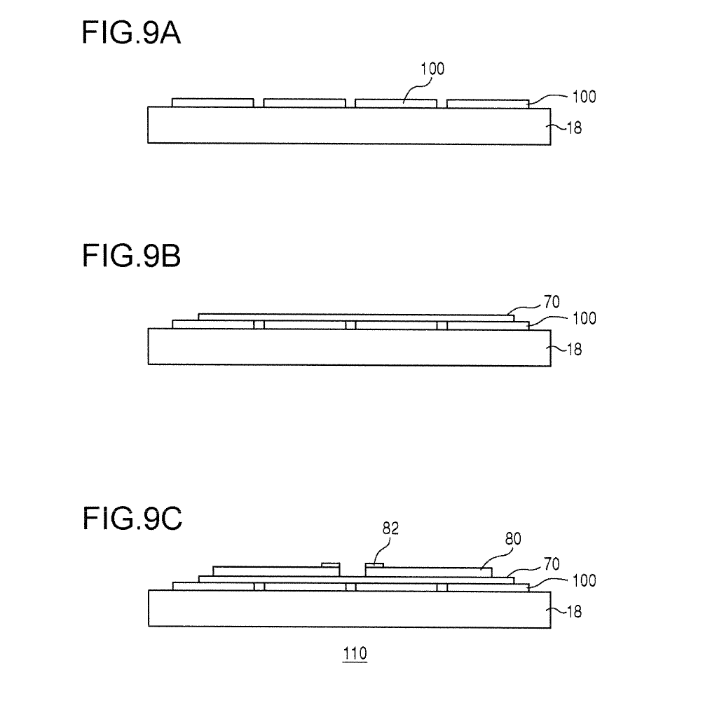

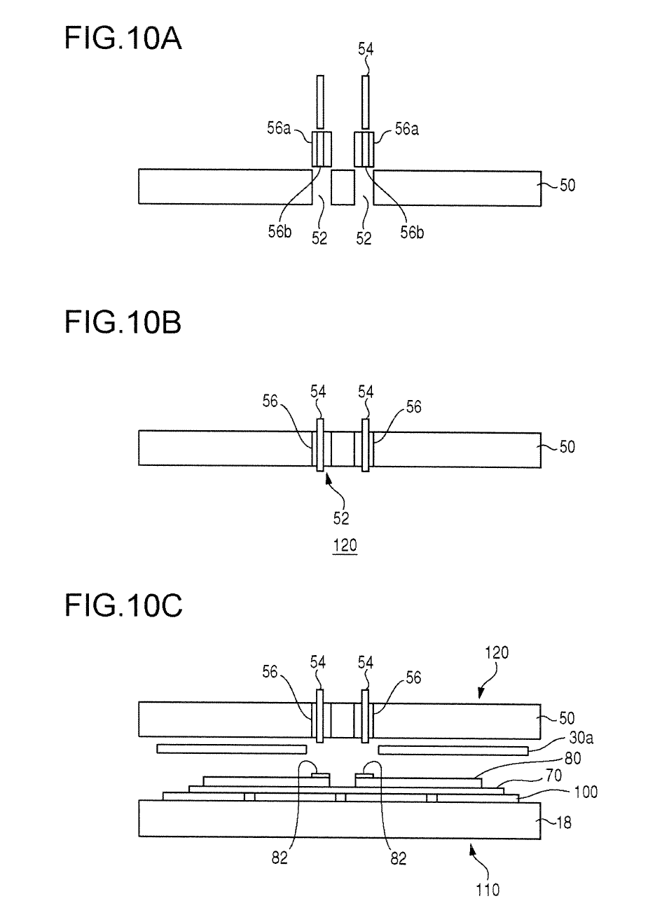

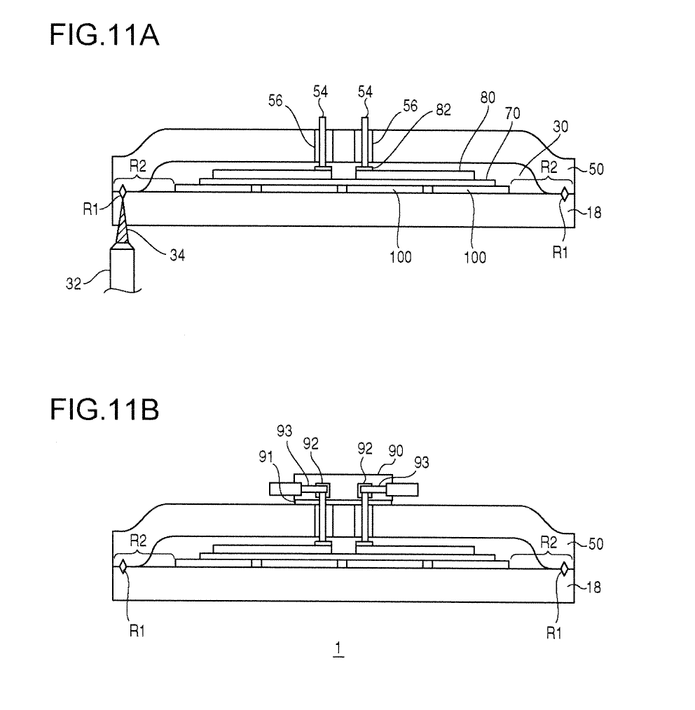

A description is now given of a modularizing process where other members, such as the current-collecting wiring and the back-side glass plate, are arranged on the translucent member 18 where a plurality of the above-described photovoltaic devices 100 are provided. FIGS. 9A to 9C are schematic cross-sectional views to explain a method for manufacturing a solar cell module according to the first embodiment. FIGS. 10A to 10C are schematic cross-sectional views to explain a method for manufacturing a solar cell module according to the first embodiment. FIGS. 11A and 11B are schematic cross-sectional views to explain a method for manufacturing a solar cell module according to the first embodiment.

If the photovoltaic devices 100 are to be modularized, the first electrodes 28n of the plurality of photovoltaic devices 100 arranged side by side and the second electrodes 28p placed adjacent thereto will be connected through the first current-collecting wirings 60 and 65, thereby connecting the plurality of photovoltaic devices 100 in series with each other (FIG. 9A).

The first current-collecting wiring 60 is connected to the first electrode 28n or the second electrode 28p by using a conductive film with an adhesive applied thereto. A vacuum laminator unit described later ensures the electric connection by press-bonded while a temperature is raised, in a range of 200° C. or below, starting from a surface of the back-side glass plate 50. Thus, damage to the photovoltaic device 100 due to the thermal stress can be suppressed.

As described earlier, the second current-collecting wiring 80 extracts the electric power, generated by the photovoltaic device 100, to the terminal box. The insulating coating material 70 is placed on the periphery of a region where the second current-collecting wiring 80 on the photovoltaic device 100 is disposed (FIG. 9B). The insulating coating material 70 is preferably a member to which a seal-like adhesive is applied on the rear face.

The second current-collecting wiring 80, which is placed on the insulating coating material 70, extends from the back-side electrode of the photovoltaic device 100, at the end edge of each of the photovoltaic devices 100 connected in series, to a position where the second current-collecting wiring 80 faces the through-hole 52 of the back-side glass plate 50 (FIG. 9C). And the conductive film 82 is arranged on top of the second current-collecting wiring 80 such that the conductive film overlaps with the metal terminal 54 in the through-hole 52 of the back-side glass plate 50 (see FIG. 9C).

As described above, through the processes shown in FIG. 9A to 9C, prepared is a first module 110 where the second current-collecting wirings 80, connected to the photovoltaic devices 100, are placed over the photovoltaic devices 100 placed on the translucent member 18.

Then, a ring-like (cylindrical) low-melting-point glass material 56a having a through-hole 56b in a central part thereof and a metal terminal 54, which is to be inserted to the through-hole 56b of the low-melting-point glass material 56a are prepared (FIG. 10A). And the low-melting-point glass material 56a and the metal terminal 54 are placed into a through-hole 52, whose diameter is 6 mm, of a back-side glass plate 50 in a state where the metal terminal 54 has been inserted to the through-hole 56b. The thickness of the low-melting-point glass material 56a may differ from that of the back-side glass plate 50; namely, the low-melting-point glass material 56a may be thicker or thinner than the back-side glass plate 50. Then, the back-side glass plate 50 in whole or in part (i.e., in part thereof near the periphery of the through-hole 52) undergoes a thermal treatment at a temperature of 300 to 400° C. and thereby the low-melting-point glass material 56a melts on the periphery of the through-hole 52. As a result, the low-melting-point glass 56a is joined to the inner circumferential surface of the through-hole 52 of the back-side glass plate 50, which in turn completely seals off the through-hole 52 (FIG. 10B). Here, the back-side glass plate 50 as used herein is more preferably a glass, having a low linear expansion coefficient, such as borosilicate glass or alkali-free glass. Use of such glass is efficient in all the more preventing the occurrence of cracks otherwise caused during the thermal treatment required for the sealing of the through-hole 52.

As described above, through the processes shown in FIG. 10A to 10C, a second module 120 is prepared. In this second module 120, the metal terminal 54, through which the electric power generated in the photovoltaic device 100 is outputted to the exterior, is fixed in the through-hole 52 formed in the back-side glass plate 50 via the low-melting-point glass 56 in a manner such that the metal terminal 54 penetrates the back-side glass plate 50 and such that the through-hole 52 is sealed.

Then, the translucent member 18 (the first module 110) and the back-side glass plate 50 (the second module 120) are arranged to face each other. And a resin sheet 30a formed of EVA, PVB, various types of olefin-based resins or the like is placed between the back-side glass plate 50 and the photovoltaic device 100 (FIG. 10C). The resin sheet 30a placed therebetween is of a size such that one side thereof is smaller than that of the back-side glass plate 50 by about 5 to 10 mm. A periphery of the through-hole 52, including a part of the resin sheet 30a corresponding to the through-hole 52 of the back-side glass plate 50, or at least a region of the resin sheet 30a corresponding to a position where the conductive film 82 is placed on the second current-collecting wirings 80 is drilled. The drilled part of the resin sheet 30a is drilled for the purpose of connecting the metal terminal 54 to the conductive film 82. Instead of the resin sheet 30a, a pasty resin or the like can be uniformly applied.

Then, a laminating process is carried out by applying (raising) a temperature of about 140° C. to about 180° C. using the vacuum laminator, while the back-side glass plate 50 (the second module 120), where the metal terminals 54 are mounted in the through-holes 52, is being overlapped above the translucent member 18 (the first module 110), where the photovoltaic devices 100 and the second current-collecting wirings 80 are placed. This laminating process softens the resin sheet 30a, placed between the second module 120 and the first module 110, and deforms it such that gaps between the photovoltaic devices 100 are filled in and the first current-collecting wirings 60 and 65 and the second current-collecting wirings 80 are buried. Then a region of the filler 30 is formed between the back-side glass plate 50 and the photovoltaic devices 100 and the translucent member 18 (FIG. 11A). The back-side glass plate 50, the photovoltaic devices 100 and the second current-collecting wirings 80 are bonded to the filler 30.

In the present embodiment, there is provided a connection process. In this connection process, by using a temperature and a pressure applied during the laminating process, the metal terminal 54 and the second current-collecting wiring 80 are electrically connected, via the conductive film 82, simultaneously with the laminating process. This structure can further reduce the infiltration of water vapor (moisture) from the through-hole 52 into the solar cell module 1, in particular. As compared with a case where an end part of the second current-collecting wiring 80 is extracted to or led out to the exterior from the through-hole 52 so as to be connected to the metal terminal, the method for manufacturing a solar cell module according to the present embodiment eliminate such the extraction of the wiring. Thus, the manufacturing process can be simplified.

The conductive film 82 may have an adhesion layer and metallic particles dispersed in the adhesion layer. Thereby, the connection reliability of the metal terminal 54 and the second current-collecting wiring 80 is improved, and the thermal stress can be mitigated.

Also, a conductive film having an adhesion layer and metallic particles dispersed in this adhesion layer may be used as the conductive member. Provision of the adhesion layer improves the adhesion properties of the second current-collecting wiring 80 and the metal terminal 54 and can therefore improve the connection reliability. Also, in the above-described connection process, the heating temperature during the laminating process may be set to a temperature at which at least the conductive film 82 is softened. The softening temperature of the conductive film 82 is lower than the heating temperature during a general connection process using solders. Thus an adverse effect from heating on the photovoltaic device 100 during the connection process can be reduced.

As in the present embodiment particularly, the photovoltaic device 100 is arranged such that, as the through-hole 52 is viewed from top, a part of the photovoltaic device 100 overlaps with the conductive film 82. If the conductive film 82 and the photovoltaic device 100 are located closer to each other, such a thermal treatment using a relatively low temperature will be effective. Consider now a solar cell module where the current-collecting is bent in a lower position of the through-hole, a wiring end part is led out from the through-hole, the through-hole through which the current-collecting wiring is passed is filled in with a sealing resin. In this case, a disconnection may possibly occur when a thermal stress acts on a bent part of the current-collecting wiring. In the present embodiment, however, the conductive film 82 lies between the metal terminal 54 and the second current-collecting wiring 80, thus eliminating the provision of such a bent part as mentioned in the above case. Hence, the connection reliability between the metal terminal 54 and the second current-collecting wiring 80 improves.

A description is now given of a method where the translucent member 18 and the back-side glass plate 50 are melt-bonded to each other. In the melt-bonding of the translucent member 18 and the back-side glass plate 50, as shown in FIG. 3, at least one of peripheries of the translucent member 18 and the back-side glass plate 50 is so bent that the translucent member 18 and the back-side glass plate 50 are firmly attached at part of the peripheral region R2. Then, a laser device 32 irradiates a laser beam 34 by focusing on a contact surface of the peripheral region R2 where the translucent member 18 and the back-side glass plate 50 are firmly attached. And the laser device 32 scans along four sides forming the outer circumference of the translucent member 18 and the back-side glass plate 50 (FIG. 11A).

Thereby, the back-side glass plate 50 is melt-bonded to the translucent member 18 at a peripheral edge of the back-side glass plate 50. This suppresses the water vapor from entering the solar cell module through a gap, between the back-side glass plate 50 and the translucent member, at a peripheral edge of the solar cell module 1. Hence, the reliability of the solar cell module 1 can be further improved.

The laser beam 34 is preferably a femto-second laser beam. That is, the laser beam 34 is preferably one having a pulse width of 1 nanosecond or less. Also, the wavelength of the laser beam 34 is preferably such that the absorption occurs on at least one of the translucent member 18 and the back-side glass plate 50. For example, the wavelength of the laser beam 34 is preferably 800 nm. The laser beam 34 is preferably irradiated under an energy density and a scanning rate enough to melt the translucent member 18 and the back-side glass plate 50. For example, the laser beam 34 is preferably irradiated such that the wavelength thereof is 800 nm, the pulse width thereof is 150 fs, the oscillation repetition frequency thereof is 1 kHz, and the pulse energy thereof is 5 microjoules (μJ) per pulse. Also, the laser beam 34 is preferably scanned at the scanning rate of 60 mm/minute. Also, the laser beam 34 may be irradiated from either a translucent member 18 side or a back-side glass plate 50 side.

Finally, the terminal box 90 is placed on the back-side glass plate 50 in such a manner as to cover the through-holes 52, and the terminal box 90 is bonded to the back-side glass plate 50 by the silicone-based or acrylic-based adhesive 91. Then, the metal terminals 54 are each directly connected to a connection metal terminal 92 or a cable 93 inside the terminal box 90 by using a solder or a metallic clip-like attachment. This completes the solar cell module 1.

Using the solar cell module and the method for manufacturing the solar cell module described above achieves advantageous effects as follows.

The metal terminal 54 and the second current-collecting wiring 80 can be electrically connected to each other simultaneously with the laminating process. Thus, the through-hole 52 can be completely sealed without any additional process, and the present embodiment can manufacture a highly reliable solar cell module where no water vapor enters through the through-hole 52.

Moreover, employed is a glass sealing structure where the translucent member 18 and the back-side glass plate 50 are melt-bonded at an outer edge portion thereof. Thus, the infiltration of water vapor from the exterior can be almost completely blocked. Hence, the solar cell module with a highly sealing performance can be obtained and the reliability is significantly enhanced.

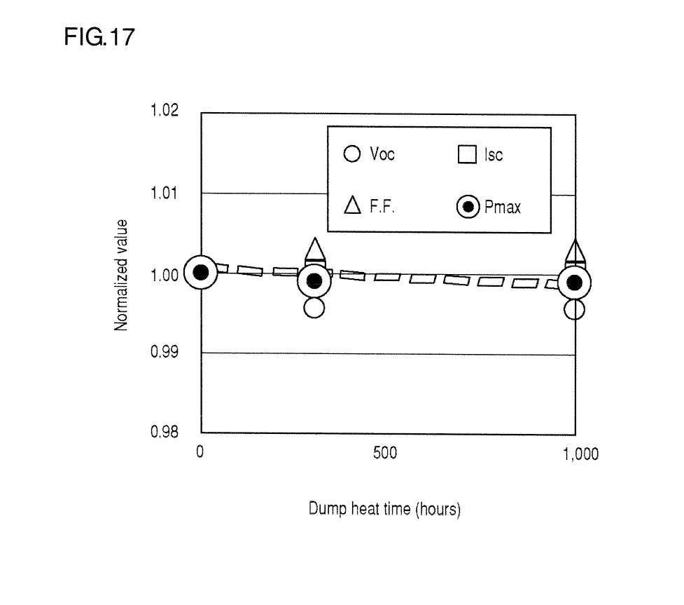

FIG. 17 is a graph showing a change in a maximum output point in a high-temperature and high-humidity testing. FIG. 17 shows not only a change in a maximum output point (Pmax) but also changes in an open voltage (Voc), a short-circuit current (Isc) and a fill factor (F.F.). The vertical axis of FIG. 17 indicates normalized values with each of values in the beginning of the testing set to 1.00, and the horizontal axis thereof indicates the time duration of the high-temperature and high-humidity testing.

At first, a soda-lime glass plate the size of which is 150 mm×150 mm×3.2 mm is prepared as the translucent member. Then, a stepped part is provided in a center of the glass plate to a degree such that crystalline cells can be contained. And a first module is fabricated by containing these cells in the stepped part. At the same time, an alkali-free glass plate the size of which is 150 mm×150 mm×2.0 mm is prepared as the back-side glass plate. Then, the metal terminals, which output the electric power to the exterior in the crystalline cells, are fixed in the through-holes formed in the back-side glass plate, via a low-melting-point glass, such that the metal terminals penetrate the back-side glass plate. And a second module where the through-holes are sealed is fabricated. Finally, the first module and the second module are arranged to face each other, and the outer edge portions thereof are melt-bonded, thereby fabricating a testing module.

As a result of the high-temperature and high-humidity testing performed on this module used for the testing, no infiltration of water content was observed and 99.9% of the initial maximum output point (Pmax) was retained even after 1000 hours aging testing.

The temperature required for the bonding of the conductive film 82 to the second current-collecting wiring 80 and the metal terminal 54 is lower than the bonding temperature using solders. Thus, thermally-caused damage to the photovoltaic device 100 at the time of solder bonding can be reduced. In the light of this, used preferably here is the conductive film 82, having a sufficient bonding strength, which can be electrically connected at a temperature (in the vicinity of 150° C.) of the laminating process. As a result, adhesion failure and connection failure are reduced, thus helping improve the yield and the reliability. Furthermore, the thermal stress can be suppressed even through the photovoltaic device 100 is located directly beneath the metal terminal 54. Thus, the through-hole 52 can be formed in any optional position of the back-side glass plate 50 and therefore the degree of freedom in designing the solar cell module can be enhanced according to the use of the module.

### Second Embodiment

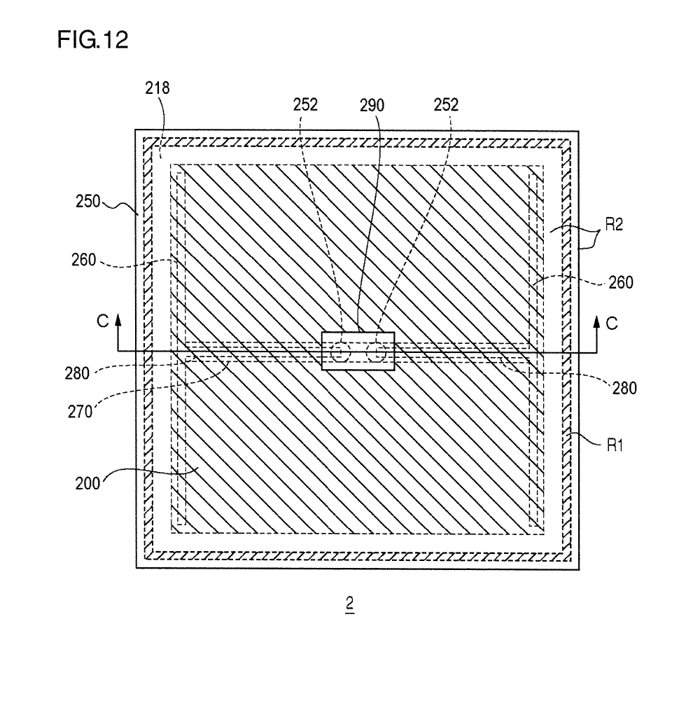

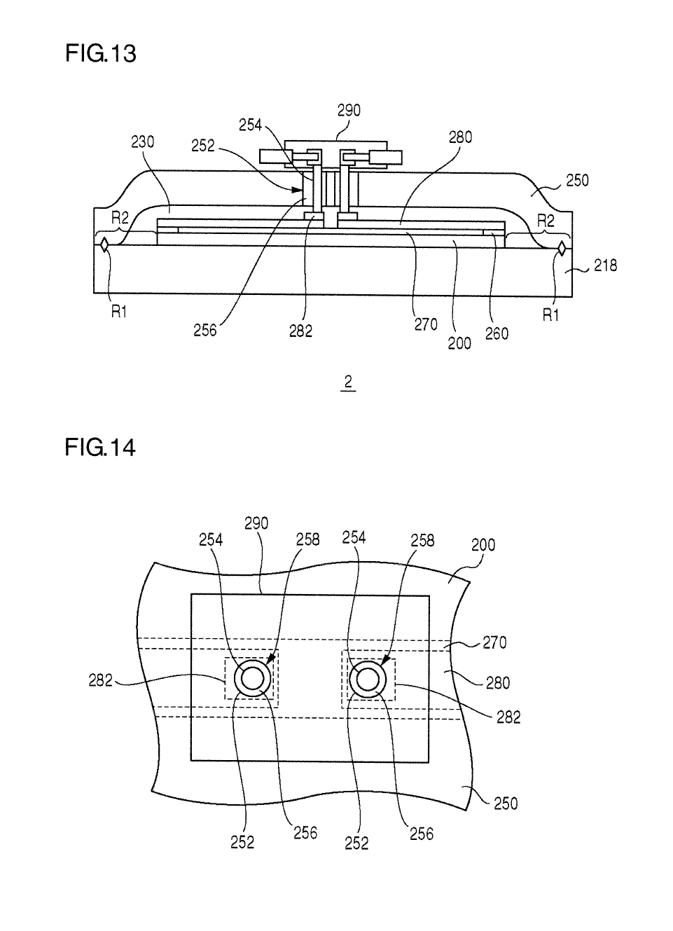

FIG. 12 is a plan view of a solar cell module 2, according to a second embodiment, viewed from a rear surface side thereof. FIG. 13 is a cross-sectional view, near a terminal box 290, taken along the line C-C of FIG. 12. FIG. 14 is a front view of the interior of the terminal box 290 shown in FIG. 12 viewed from a rear surface side thereof.

The solar cell module 2 includes a translucent member 218, which is disposed on a light-receiving surface side, a back-side glass plate 250, which is so provided as to face the translucent member 218, and a photovoltaic device 200 provided between the translucent member 218 and the back-side glass plate 250. A filler 230 is provided between the back-side glass plate 250, the photovoltaic device 200 and the translucent member 218. The second embodiment differs from the first embodiment in that the photovoltaic device 200 comprises a plurality of thin-film solar cells.

The photovoltaic device 200 is configured such that a plurality of thin-film solar cells are connected in series or in parallel with each other. The plurality of thin-film solar cells are structured such that a transparent electrode, a photoelectric conversion layer and a back-side electrode are sequentially stacked on the translucent member 218. And the plurality of thin-film solar cells are isolated in series or in parallel with each other by a processing method using a laser. The photoelectric conversion layer as used herein is amorphous silicon, microcrystalline silicon, a stack structure formed by a plurality of silicon thin films, a compound-based material, or the like. ZnO or SnO₂ is used for the transparent electrode, and Ag or the like is used for the back-side electrode.

A description is now given of a path through which the electric power generated by the photovoltaic device 200 according to the second embodiment is extracted.

As shown in FIG. 12, FIG. 13 and FIG. 14, a first current-collecting wiring 260 and a second current-collecting wiring 280 are formed for the purpose of extracting the electric power generated by the photovoltaic device 200. The first current-collecting wiring 260 is a wiring used to collect the current from the photovoltaic device 200 separated in parallel, and the second current-collecting wiring 280 is a wiring by which to connect between the first current-collecting wiring (start point) 260 and the terminal box 290 (end point).

The first current-collecting wirings 260 are extended over the back-side electrode of the photovoltaic device 200. The first current-collecting wirings 260 are formed to connect the positive electrodes of the photoelectric layer separated in parallel near a distal edge of the solar cell module 2 to each other and connect the negative electrodes thereof to each other. Thus, the first current-collecting wiring 260 is extended along a direction perpendicular to a parallely-divided direction of the photoelectric conversion layer. In the second embodiment, as shown in FIG. 12, the first current-collecting wirings 260 are extended, along the vertical direction, at the distal edges thereof. With this arrangement and structure, the positive electrodes connected in series in the photovoltaic device 200 are connected in parallel with each other and the negative electrode are connected in parallel with each other.

An insulating coating material 270 is disposed in order to form an electrical insulation between the second current-collecting wirings 280 and the back-side electrodes of the photovoltaic device 200. As shown in FIG. 12 and FIG. 13, the insulating coating material 270 is extended, over the back-side electrodes of the photovoltaic device 200, in between a vicinity of the first current-collecting wirings 260 at the left and right distal edges of the solar cell module 2 and a vicinity of the terminal box 290 disposed in a central part thereof. The insulating coating material 270 as used herein is the same material as one used for the insulating coating material 70 according to the first embodiment.

As shown in FIG. 12 to FIG. 14, the second current-collecting wirings 280 are placed partially on top of and are extended from the left and right first current-collecting wirings 260. Also, the second current-collecting wirings 280 are placed on top of and along the insulating coating material 270 toward the central part of the solar cell module 2. The insulating coating material 270 is held (sandwiched) between the second current-collecting wirings 280 and the back-side electrodes of the photovoltaic device 200, thereby retaining the electric insulation therebetween. On the other hand, one end of the second current-collecting wiring 280 is extended up to a top face of the first current-collecting wiring 260 and is electrically connected to the first current-collecting wiring 260. For example, the second current-collecting wiring 280 is electrically connected to the first current-collecting wiring 260 using ultrasonic solders or the like. The other end of the second current-collecting wiring 280 is electrically connected to a terminal inside the terminal box 290 via a conductive film 282 and a metal terminal 254, both of which will be described later.

As shown in FIG. 14, a current extraction member of the solar cell module 2 is provided in the surface of the back-side glass plate 250, and includes a metal terminal 254 that functions as an electrically-conducting path through which the electric power generated in the photovoltaic device 200 is outputted to the exterior. In the back-side glass plate 250, two through-holes 252, each of whose diameter is 6 mm, are formed in a central part of the back-side glass plate 250, and the metal terminal 254 is placed in the through-hole 252 such that the through-hole 252 runs through the metal terminal 254. Also, the metal terminal 254 is melt-bonded to the back-side glass plate 250, in the inner circumferential surface of the through-hole 252, via a low-melting-point glass 256 (i.e., with the low-melting-point glass 256 placed between the metal terminal 254 and the back-side glass plate 250). The low-melting-point glass 256 as used herein is the same as the low-melting-point glass 56 according to the first embodiment.

The metal terminal 254 may be an alloy of iron and nickel with the ratio of iron to nickel being 50:50, for instance. Such an alloy as this has a linear expansion coefficient that is relatively close to that of the low-melting-point glass, so that the occurrence of cracks or the like otherwise caused by a thermal expansion of the low-melting-point glass can be suppressed.

As illustrated in FIG. 12 to FIG. 14, the second current-collecting wiring 280 is arranged such that the second current-collecting wiring 280 is connected to the photovoltaic device 200 and extend below a sealing member 258. The conductive film 282, which serving as a conductive member, is arranged on top of the second current-collecting wiring 280 and is also arranged below the sealing member 258. The conductive film 282 is arranged on top of the second current-collecting wiring 280 and is placed underneath the metal terminal 254, which is placed in the through-hole 252 (see FIG. 13 and FIG. 14). A top face of the conductive film 282 is in contact with a lower end of the metal terminal 254, whereas a bottom face thereof is in contact with a top face of the second current-collecting wiring 280. Thus, the conductive film 282 electrically conducts between the metal terminal 254 and the second current-collecting wiring 280. In other words, the second current-collecting wiring 280 and the metal terminal 254 electrically conduct with each other via the conductive film 282 placed therebetween. And this connection portion is overlapped with the photovoltaic device 200 via the insulating coating material 270.

In the present embodiment, the conductive film 282, having a sufficient bonding strength, which can achieve an excellent electric connection at a temperature (in the vicinity of 150° C.) of the laminating process is used for the bonding of the second current-collecting wirings 280 and the metal terminals 254 is.

The metal terminal 254 is connected to a connection metal terminal inside the terminal box 290 by using a solder or a metallic clip-like attachment. The terminal box 290 is bonded to the back-side glass plate 250 by a silicone-based or acrylic-based adhesive. This completes the solar cell module 2 according to the second embodiment.

A method for manufacturing the solar cell module 2 is similar to that according to the first embodiment. First prepared is a first module where the second current-collecting wirings 280, connected to the photovoltaic device 200, are placed over the photovoltaic device 200 placed on the translucent member 218. Then, a second module is prepared. In this second module, the metal terminal 254, through which the electric power generated in the photovoltaic device 200 is outputted to the exterior, is fixed in the through-hole 252 formed in the back-side glass plate 250 via the low-melting-point glass 256 in a manner such that the metal terminal 254 penetrates the back-side glass plate 250 and such that the through-hole 252 is sealed. Then, the laminating process is carried out while the back-side glass plate 250 (the second module), is being overlapped above the translucent member 218 (the first module). In so doing, similar to the first embodiment, the connection process is carried out wherein the metal terminal 254 and the second current-collecting wiring 280 are electrically connected, via the conductive film 282, simultaneously with the laminating process.

The same advantageous effects are achieved when used are the solar cell module 2 and its manufacturing method, described as above, according to the second embodiment.

The present disclosure has been described by referring to each of the above-described embodiments. However, the present disclosure is not limited to the above-described embodiments only, and those resulting from any combination of them or substitution as appropriate are also within the scope of the present disclosure. Also, it is understood by those skilled in the art that various modifications such as changes in the order of combination or processings made as appropriate in each embodiment or changes in design may be added to the embodiments based on their knowledge and the embodiments added with such modifications are also within the scope of the present disclosure.

In the first embodiment, the back-side bonding type photoelectric conversion elements where both an anode and a cathode are disposed on the rear surface side are used as the photovoltaic device. However, the same advantageous effects can be achieved when used are photoelectric conversion elements configured such that different conductive types are provided on the rear surface side and the surface side, as with a conventional crystalline Si cell.

In each of the above-described embodiments, one metal terminal 54 or 254 is placed in each of the two through-holes 52 or 252 of the back-side glass plate. Instead, a plurality of metal terminals may be placed in each through-hole, for instance. Further, three or more through-holes may be arranged. In such a case, too, the glass can be sealed using the similar method and the similar advantageous effects can be achieved.

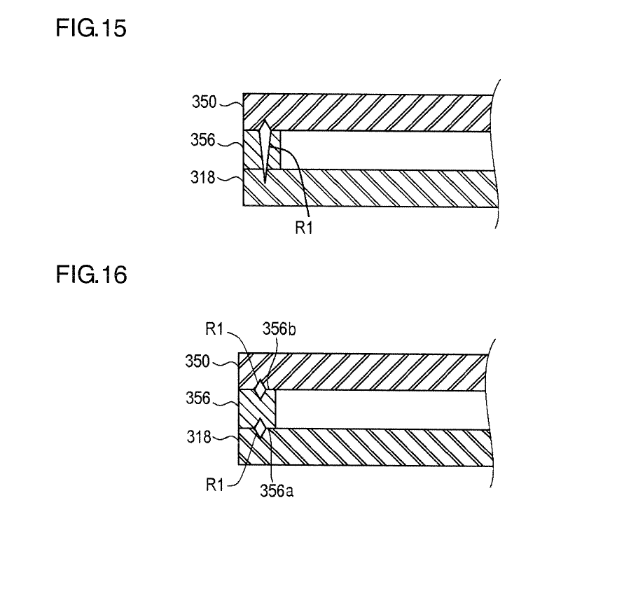

In each of the above-described embodiments, the peripheral edges of the translucent member 18 (218) and the back-side glass plate 50 (250) are directly melt-bonded to each other. However, there may be cases where the thickness of the photovoltaic device 100 (200) and the wiring and the like provided inside the solar cell module 1 (2) gets large. In this case, it is difficult to firmly attach them with each other at the peripheral edges thereof by bending at least one of the translucent member and the back-side glass plate. In such cases as this, methods shown in FIG. 15 and FIG. 16 can be used.

FIG. 15 is a diagram showing a modification of the melt-bonding of the translucent member and the back-side glass plate. FIG. 16 is a diagram showing another modification of the melt-bonding of the translucent member and the back-side glass plate.

If a gap between the peripheral edges of a translucent member 318 and a back-side glass plate 350 is larger, a spacer 356 may be formed, as shown in the cross-sectional view of FIG. 15 and then the spacer 356 may be melted using the above-described laser device 32 so as to achieve the melt-boding, in a joining region R1, between the translucent member 318 and the back-side glass plate 350.

The spacer 356 is preferably formed of a material containing an element, such as Si, SiO or SiO₂, with which the translucent member 318 and the back-side glass plate 350 can be melt-bonded to each other. For example, a spacer 356 formed in a frame shape may be formed as follows. That is, the aforementioned glass frit is applied to the outer circumference of the back-side glass plate 350 by the screen printing method and then is burnt.

Also, the laser beam 34 can be irradiated from either a translucent member 318 side or a back-side glass plate 350 side. If, for example, as in a crystalline silicon solar cell, the photovoltaic device 100 (including a silicon substrate) itself is thick, the solar cell may be configured such that, as shown in FIG. 16, a surface 356a of the spacer 356 and the translucent member 318 are melt-bonded to each other in the joining region R1 and such that a rear surface 356b of the spacer 356 and the back-side glass plate 350 are melt-bonded to each other in the joining region R1.

Also, for example, the solar cell modules or method for fabricating the solar modules characterized by the following (1) to (8) in combination are also encompassed by the embodiments of the present disclosure.

(1) A solar cell module includes:

a translucent member disposed at a light-receiving side;

a glass plate provided in such a position as to face the translucent member, the glass plate having a through-hole;

a photovoltaic device provided between the translucent member and the glass plate;

a sealing portion that seals the through-hole;

a wiring connected to the photovoltaic device, the wiring being arranged in such a manner as to extend below the sealing portion; and

a conductive member arranged on top of the wiring and below the sealing portion,

the sealing portion includes:
a glass member joined to an inner circumferential surface of the through-hole; and
a metal terminal that outputs electric power, generated in the photovoltaic device, to an exterior, the metal terminal being joined to the glass member in a manner such that the metal terminal penetrates the glass member,

wherein the metal terminal connects to the wiring by way the conductive member.

(2) In the solar cell module according to (1), the conductive member may be a conductive film.

(3) In the solar cell module according to (2), the conductive film may have an adhesion layer and metallic particles dispersed in the adhesion layer.

(4) In the solar cell module according to any one of (1) to (3), the photovoltaic device may be arranged such that, as the through-hole is viewed from top, a part of the photovoltaic device overlaps with the conductive member.

(5) In the solar cell module according to any one of (1) to (4), the glass member may be a low-melting-point glass whose glass transition temperature thereof is 600° C. or below.

(6) In the solar cell module according to any one of (1) to (5), a periphery of the glass plate is melt-bonded to the translucent member.

(7) A method for fabricating a solar cell module includes:

a process for preparing a first module on a photovoltaic device provided on a translucent member, wherein a wiring connected to the photovoltaic device is provided in the first module;

a process for preparing a second module wherein a metal terminal, through which electric power generated in the photovoltaic device is outputted to an exterior, is fixed in a through-hole formed in a glass plate, via a glass member, in a manner such that the metal terminal penetrates the glass plate and such that the through-hole is sealed; and

a process for connecting the metal terminal to the wiring with a conductive member placed between the metal terminal and the wiring such that the first module and the second module face each other.

(8) In the method, for fabricating a solar cell module, according to (7), a conductive film, having an adhesion layer and metallic particles dispersed in the adhesion layer, may be used as the conductive member, and the process for connecting the metal terminal to the wiring may be performed such that heating is carried out at a temperature at which at least the conductive film is softened.

### INDUSTRIAL APPLICABILITY

The present disclosure can be used for a solar cell module.

What is claimed is:

1. A solar cell module comprising:
a translucent member disposed at a light-receiving side;
a glass plate provided in such a position as to face the translucent member, the glass plate having a through-hole;
a photovoltaic device provided between the translucent member and the glass plate;
a sealing portion that seals the through-hole;
a wiring connected to the photovoltaic device, the wiring being arranged in such a manner as to extend below the sealing portion; and
a conductive member arranged on top of the wiring and below the sealing portion,
the sealing portion including:
a glass member joined to an inner circumferential surface of the through-hole; and
a metal terminal that outputs electric power,
generated in the photovoltaic device, to an exterior, the metal terminal being joined to the glass member in a manner such that the metal terminal penetrates the glass member,
wherein the metal terminal connects to the wiring by way the conductive member.

2. The solar cell module according to claim 1, wherein the conductive member is a conductive film.

3. The solar cell module according to claim 2, wherein the conductive film has an adhesion layer and metallic particles dispersed in the adhesion layer.

4. The solar cell module according to claim 1, wherein the photovoltaic device is arranged such that, as the through-hole is viewed from top, a part of the photovoltaic device overlaps with the conductive member.

5. The solar cell module according to claim 1, wherein the glass member is a low-melting-point glass whose glass transition temperature thereof is 600° C. or below.

6. The solar cell module according to claim 1, wherein a periphery of the glass plate is melt-bonded to the translucent member.

7. A method, for fabricating a solar cell module, including:
preparing a first module on a photovoltaic device provided on a translucent member, wherein a wiring connected to the photovoltaic device is provided in the first module;
preparing a second module wherein a metal terminal, through which electric power generated in the photovoltaic device is outputted to an exterior, is fixed in a through-hole formed in a glass plate, via a glass member, in a manner such that the metal terminal penetrates the glass plate and such that the through-hole is sealed; and
connecting the metal terminal to the wiring, with a conductive member placed between the metal terminal and the wiring, such that the first module and the second module face each other.

8. The method, for fabricating a solar cell module, according to claim 7, wherein a conductive film, having an adhesion layer and metallic particles dispersed in the adhesion layer, is used as the conductive member in the connecting and wherein the connecting is performed such that heating is carried out at a temperature at which at least the conductive film is softened.
